(19) United States
(12) Patent Application Publication
(10) Pub. No.: US 2024/0201242 A1
(43) Pub. Date: Jun. 20, 2024

(54) DEVICE FOR MONITORING A POWER DISTRIBUTOR OF A MOTOR VEHICLE

(71) Applicant: Robert Bosch GmbH, Stuttgart (DE)

(72) Inventors: Albert Geiger, Eberdingen (DE); Andreas Beck, Niederstetten (DE); Joerg Jehlicka, Rutesheim (DE); Patrick Bauer, Stuttgart (DE); Roman Gronbach, Stuttgart (DE)

(21) Appl. No.: 18/555,817

(22) PCT Filed: Jul. 20, 2022
(86) PCT No.: PCT/EP2022/070354

§ 371 Date: Oct. 17, 2023

(30) Foreign Application Priority Data
Aug. 16, 2021 (DE) 10 2021 208 935.6

(51) Int. Cl. G01R 31/00; G01R 19/165; H02H 7/22

(52) U.S. Cl. CPC G01R 31/006; G01R 19/16571; H02H 7/22

(57) ABSTRACT

A device for monitoring a power distributor of a motor vehicle. The device includes a main path, and an additional path connected in parallel thereto. The paths are arranged between an on-board electrical subsystem for at least one safety-relevant load and a further on-board electrical subsystem for at least one non-safety-relevant load. The main path includes at least one switch. The additional path has at least one switch. The power distributor includes at least one evaluation device for detecting a state that is critical to the on-board electrical subsystem at the on-board electrical subsystem for the safety-critical load, and for opening the switch of the main path and/or of the additional path when the critical state is detected. A monitoring device is provided for monitoring, independently of the evaluation device, a current flowing through the additional path and for actuating the switch of the additional path.

### FIELD

The present invention relates to a device for monitoring a power distributor of a motor vehicle.

### BACKGROUND INFORMATION

German Patent Application No. DE 10 2018 212507 A1 describes an electronic power distributor for an on-board energy system, comprising at least one first connection for safety-critical loads and at least one second connection for a branch in which at least one load is arranged. The power distributor further comprises an electronic fuse which, in a closed state, allows a current flow to the at least one second connection and, in an open state, interrupts this current flow, wherein a bypass to the electronic fuse is provided, which, in an operating state in which the electronic fuse is open, allows the current flow to the at least one second connection.

### SUMMARY

A problem addressed by the present invention is that of providing a device that reliably monitors the power distributor with a low quiescent current consumption. This problem may be solved by features of the present invention.

According to an example embodiment of the present invention, since, in addition to an evaluation means (i.e., device), at least one monitoring means (i.e., device) is provided for monitoring, independently of the evaluation means, a current flowing via the additional path and for actuating at least the switching means (i.e., the switch) of the additional path, the monitoring means can be active alone, in particular in sleep mode or during the wake-up phase. By suitable selection of the monitoring means, it can be optimized in terms of quiescent current minimization. The evaluation means, such as a microcontroller, can in particular remain switched off in sleep mode. By means of the monitoring means, components through which current flows can be protected from destruction, for example in the event of a short circuit.

In an expedient development of the present invention, the monitoring means comprises at least one wake-up comparator, which activates the monitoring means when the current flowing via the additional path reaches a threshold value. In a normal sleep mode scenario with non-critical load changes, this monitoring means has no current consumption. Only upwards of an adjustable threshold value does the monitoring means with associated measuring circuit become active and, if necessary, open the additional path in the event of an overload. The quiescent current consumption is thereby minimized.

In an expedient development of the present invention, it is provided for the monitoring means to distinguish between at least two time ranges in which different threshold values for the current are provided. Different requirements, in particular for a static load case and a dynamic load case, can thus be represented, whereby the components of the additional path can be well protected.

In an expedient development of the present invention, the monitoring means comprises at least one dynamic overcurrent comparator, wherein the associated threshold value is selected as a function of a time duration during which the current flows.

As a result, the monitoring means permits short pulse-like current profiles that range within the load capacity of the additional path. Currents that exceed the static load capacity but not the dynamic load capacity of the components used can thus be permitted in the additional path for a short time. In particular, for this purpose, the dynamic overcurrent comparator is particularly expediently designed to permit a higher current for a shorter duration or a lower current for a longer duration. Particularly preferably, an exponential relationship between the permitted current and the associated duration of the current is represented in the dynamic overcurrent comparator. This function can particularly preferably be realized via a filter, in particular using a capacitor or an RC element. The function produced relatively simply in this way is very well suited to a typical dynamic power limit of the components in the additional path.

In an expedient development of the present invention, the monitoring means comprises at least one static overcurrent comparator, which generates a switch-off signal for opening the switching means of the additional path when the current reaches a further threshold value. A static maximum current that the components of the additional path can carry can thus be defined, as can the static load that can be supplied therewith.

In an expedient development of the present invention, the switching means (i.e., the switch) of the main path is open in a sleep mode or a wake-up phase, while the switching means of the additional path is closed in a sleep mode or the wake-up phase, and/or the evaluation means is not active in the sleep mode or the wake-up phase. A high level of safety of the power distributor can thus be achieved even when the evaluation means is switched off and/or in sleep mode, since the monitoring means can be used as a fallback solution in the event of a fault in the evaluation means. This is particularly advantageous for achieving certain ASILs. For this purpose, in a preferred development, the monitoring means can be activated when there is a fault in the main path and/or a fault in the power distributor and/or a fault in the evaluation means.

In an expedient development of the present invention, the monitoring means comprises at least one timing element, which is designed such that the dynamic overcurrent comparator is active up to a time period, in particular from activation, and that after the time period, in particular after activation, is reached, the static overcurrent comparator is additionally active. A reliable protective effect of the components of the additional path can thus be achieved for different fields of application.

In an expedient development of the present invention, it is provided for the dynamic overcurrent comparator to comprise at least one differential amplifier and/or at least one filter with at least one capacitor or an RC element and/or at least one threshold value comparator. The circuit blocks can thus be constructed with discrete components that are relatively favorable in the automotive field.

In an expedient development of the present invention, the monitoring means comprises at least one power supply, which can only be activated when the current flowing through the additional path reaches a threshold value. The supply is thus activated only if necessary.

In an expedient development of the present invention, the additional path has at least one resistor, in particular for current limitation and/or as a measuring resistor for detecting the current. The additional path can be used in a targeted manner for precharging an on-board electrical subsystem if, for example, a battery is connected to the safety-relevant on-board electrical subsystem. A possible capacitive portion of the on-board electrical subsystem ensures a high charging current via the additional path, which is also protected from overload thanks to the monitoring means.

In an expedient development of the present invention, the evaluation means is designed as a hardware circuit, in particular without a controller. Rapid switching times, which would be difficult to realize on the software side, can thus be reliably achieved with a low quiescent current consumption.

Further expedient developments of the present invention are disclosed herein.

### BRIEF DESCRIPTION OF THE DRAWINGS

FIG. 1 shows, by way of example, an exemplary embodiment of the power distributor of the present invention, which connects two on-board electrical subsystems to one another.

FIG. 2 shows a block diagram of the individual components of an overcurrent monitoring circuit, according to an example embodiment of the present invention.

FIG. 3 shows a switch-off characteristic of a dynamic overcurrent comparator, according to an example embodiment of the present invention.

FIG. 4 shows a circuit arrangement for current measurement, according to an example embodiment of the present invention.

FIG. 5 shows a circuit arrangement of a wake-up comparator, according to an example embodiment of the present invention.

FIG. 6 shows a circuit arrangement of a static overcurrent comparator, according to an example embodiment of the present invention.

FIG. 7 shows a circuit arrangement of a dynamic overcurrent comparator, according to an example embodiment of the present invention.

FIG. 8 shows a circuit arrangement of a timing element, according to an example embodiment of the present invention.

FIG. 9 shows a circuit arrangement of a suppression circuit of the output signal of the static overcurrent comparator, according to an example embodiment of the present invention.

FIG. 10 shows a circuit arrangement of a power supply, according to an example embodiment of the present invention.

### DETAILED DESCRIPTION OF EXAMPLE EMBODIMENTS

The present invention is illustrated schematically on the basis of an exemplary embodiment and will be described in detail below with reference to the figures.

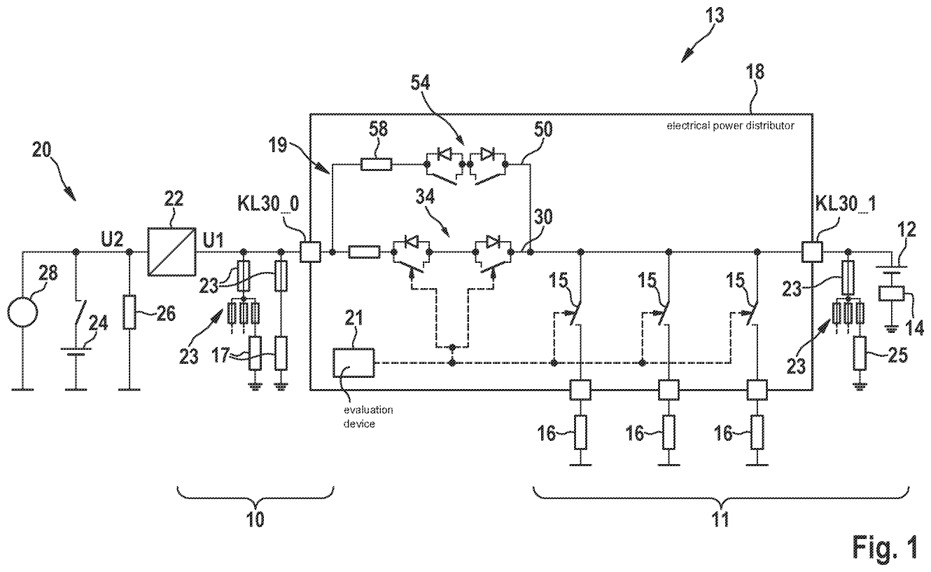

FIG. 1 shows a possible topology of an energy supply system, consisting of an on-board electrical system 13, which comprises an energy store 12, in particular a battery 12 with an associated sensor 14, preferably a battery sensor, and a plurality of in particular safety-relevant loads 16, which are protected and actuated by an electrical power distributor 18. The loads 16 are special loads having high demands or a high protection requirement, generally referred to as safety-relevant loads 16. For example, in this case an electrical steering system and/or a brake system are components which must be supplied with power in order to ensure steering and/or braking of the vehicle in the event of a fault. For this purpose, corresponding characteristic variables of the load 16 in question are detected separately and, in the event of a deviation from tolerable values, the corresponding switch 15 is opened to protect the load 16 in question. The on-board electrical system 13 consists of a safety-relevant on-board electrical subsystem 11 and a non-safety-relevant on-board electrical subsystem 10. The safety-relevant on-board electrical subsystem 11 can be disconnected from the non-safety-relevant on-board electrical subsystem 10 by the power distributor 18, in particular in the event of a fault or critical state of the non-safety-relevant on-board electrical subsystem 10. The safety-relevant on-board electrical subsystem 11 is, for example, an on-board electrical subsystem 11 that is ASIL-certified (for example according to DIN ISO 26262) and comprises at least one of the safety-relevant loads 15, 16 and can optionally be equipped with a dedicated energy store 12 for power support. The non-safety-relevant on-board electrical subsystem 10 comprises at least one non-safety-relevant load 17; these can be, for example, so-called QM loads. However, this does not exclude at least one further safety-relevant load also being arranged in the non-safety-relevant on-board electrical subsystem 10, for example in the case of a redundant design of the safety-relevant loads. The non-safety-relevant on-board electrical subsystem 10 is an on-board electrical system that is not ASIL-certified.

The energy store 12 is likewise connected to a connection (terminal KL30_1) of the power distributor 18. The sensor 14 is able to detect an electrical characteristic variable, for example a voltage Ub, at the energy store 12 and/or a current Ib through the energy store 12 and/or a temperature Tb of the energy store 12. The sensor 14 can determine, for example, the state of charge SOC of the energy store 12 or further characteristic variables of the energy store 12 from the determined electrical characteristic variables Ub, Ib, Tb. An additional supply branch for at least one further load 25 is optionally also provided at the further connection (KL30_1) of the power distributor 18 to which the energy store 12 is also connected. The load 25 is secured via a fuse 23. Further loads 25 can also be provided, which can also be secured via fuses 23. These loads 25 are those which are also to be supplied with energy by the energy store 12 when the switching means (i.e., switch) 19 is disconnected or opened in the power distributor 18, that is to say preferably safety-critical loads 25 or loads 25 which are critical in view of the generation of disturbances with respect to power supply reliability. An (optional) safety-relevant or safety-critical on-board electrical system path or on-board electrical subsystem 11 is thus connected to the connection KL30_1.

The power distributor 18 is able to determine corresponding characteristic variables such as voltage Uv and current Iv of the loads 16. In addition, the power distributor 18 is also able to determine corresponding characteristic variables of the energy store 12 such as voltage Ub and/or current Ib and/or temperature Tb. For this purpose, the power distributor 18 contains the corresponding sensors. Likewise, the power distributor 18 has corresponding evaluation means (i.e., device) 21, such as a microcontroller, to store and evaluate detected variables. The evaluation means 21 is used to ascertain critical states, in particular of the safety-relevant on-board electrical subsystem 11, for example to detect an overcurrent and/or an undervoltage or overvoltage at the on-board electrical subsystem 11 for the safety-relevant load 16, 25. For this purpose, corresponding characteristic variables are detected and compared with suitable threshold values. The evaluation means 21 used is a microcontroller, for example. The microcontroller or the evaluation means 21 is furthermore able to actuate corresponding switches 15 or the switching means (i.e., switch) 34 of a high-current capable disconnect switch 34 in the main path 30 or a switching means (i.e., switch) 54 in an additional path 50. The additional path 50 is connected in parallel with the main path 30. The additional path 50 comprises the switching means 54 and a resistor 58, in particular a current-limiting resistor 58, arranged in series for this purpose. In normal operation, both paths 30, 50 are active in parallel, i.e., their switching means 34, 54 are closed. Furthermore, the additional path 50 is used to precharge the non-safety-relevant on-board electrical subsystem 10 if, for example, an energy store is connected to the safety-relevant on-board electrical subsystem 11 for the first time. The capacitive portion of the non-safety-relevant on-board electrical subsystem 10 ensures a high charging current via the additional path 50, which in this scenario must also be protected from overload.

A corresponding disconnecting or coupling function, in particular of the two on-board electrical system branches (on-board electrical subsystem 10 for non-safety-relevant loads 17 at connection KL30_0; further on-board electrical subsystem 11 for safety-relevant loads 16, 25) can be realized via the switching means 34. This function is used in particular as a safety function in order to prevent the effects of critical states such as overvoltages or undervoltages and/or overcurrents and/or thermal overloading. In the event of a fault, the two on-board electrical subsystems 10, 11 can be disconnected from one another by the power distributor 18 by opening the switching means 34, 54.

The on-board electrical system 13 has a lower voltage level U1 than an optionally provided high-voltage on-board electrical system 20, for example it can be a 14 V on-board electrical system. A DC-DC converter 22 is arranged between the on-board electrical system 13 and the high-voltage on-board electrical system 20. The high-voltage on-board network 20 comprises, by way of example, an energy store 24, for example a high-voltage battery, possibly with an integrated battery management system, shown by way of example as a load 26, for example a comfort load such as an air-conditioning system which is supplied with an increased voltage level, etc., and an electric machine 28. In this context, a high voltage is understood to mean a voltage level U2 higher than the voltage level U1 of the on-board electrical system 13. For example, it could be a 48-volt on-board electrical system. Alternatively, the voltage levels could be even higher, particularly in vehicles with electric drive. Alternatively, the high-voltage on-board electrical system 20 could be omitted entirely.

By way of example, a battery or accumulator is described as a possible energy store 12, 24 in the exemplary embodiment. Alternatively, however, other energy stores suitable for this task can likewise be used, for example on an inductive or capacitive basis, fuel cells, capacitors or the like.

Particularly preferably, the switching means 34, 54 are formed in each case by at least two switching elements connected anti-serially (in series with one another, but oppositely directed, for example “back-to-back” or with a common source connection), preferably using power semiconductors, particularly preferably FETs or MOSFETs. Instead of MOSFETs, relays, bipolar transistors or IGBTs with parallel diodes etc. can also be used, for example.

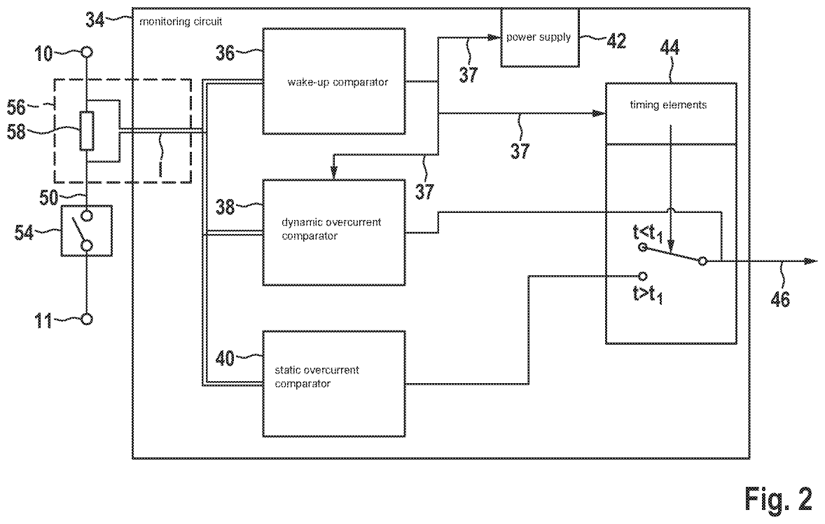

The additional path 50 is also referred to as a cold boot path or cold start path. The additional path is active throughout the life cycle of a control unit in which the power distributor 18 is implemented. In sleep mode and/or in the wake-up phase, the additional path 50 alone connects the non-safety-relevant on-board electrical subsystem 10 to the safety-relevant on-board electrical subsystem 11. The main path 30 is thus open in sleep mode and/or in the wake-up phase. At these points in time, there is no microcontroller-assisted monitoring of the current I. The evaluation means 21 or associated microcontroller is not active in sleep mode. In the wake-up phase, the microcontroller starts up. The energy input into the additional path 50 is thus also not monitored by the evaluation means 21. A monitoring means 34 or an overcurrent monitoring circuit according to FIG. 2 is provided for monitoring the additional path 50 in the sleep and/or wake-up phase. The monitoring means (i.e., device) 34 is preferably implemented purely in hardware. The monitoring means 34 is used as overload protection without quiescent current for the additional path 50 or the cold boot path. The components of the additional path 50 through which current flows are thus protected from destruction, for example in the event of a short circuit. Low quiescent current values are important requirements for a continuously supplied control unit such as the power distribution means 18. In a normal sleep mode scenario with non-critical load currents, the monitoring circuit 34 has no current consumption. Only upwards of an adjustable (current) threshold value I1 does the measuring circuit or a current measurement means (i.e., device (s)) 56 become active and optionally open the additional path 50 or the switching means 54 arranged in the additional path 50. A current/time-dependent switch-off characteristic is implemented, which can be adapted to the load capacity of the switching means 54 (for example MOSFETs) and the current measurement means 56 (shunt resistors) in the additional path 50. Furthermore, the monitoring means 34 can be used as a fallback solution in the event of a failure of the evaluation means 21 or of the main controller, in order to achieve certain ASILS.

Here, the monitoring means 34 of the additional path 50 is divided into at least two time ranges (t<t1; t>t1). The two time ranges are linked via a simple timing element 44.

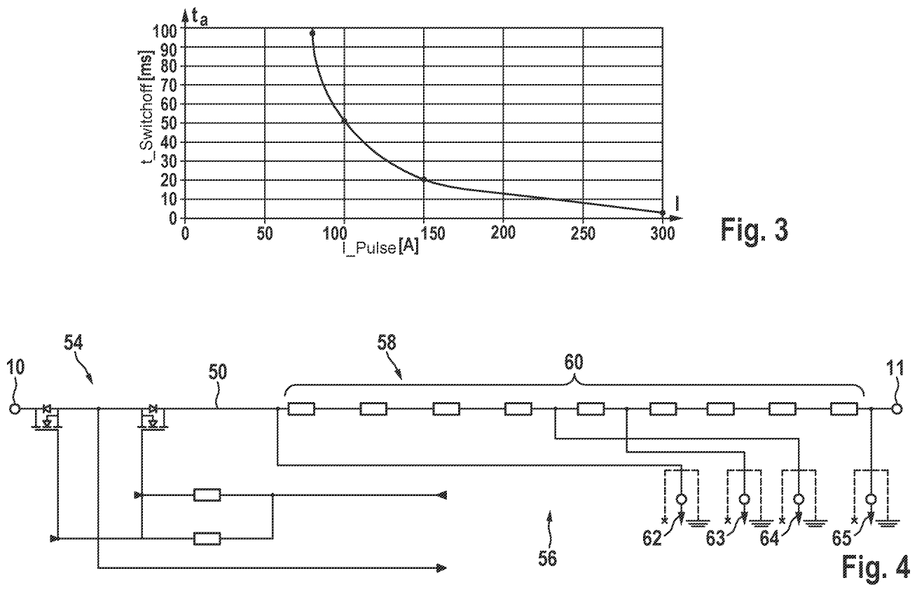

In a first time range, for example t1<700 ms, the monitoring circuit 34 allows short pulse-like current profiles which range within the load capacity of the additional path 50. For this purpose, the I-t function shown in FIG. 3 is stored and implemented in hardware. Currents that briefly exceed the static load capacity but not the dynamic load capacity of the components used in the additional path 50 are thus possible via the additional path 50. The filter 74 used in the monitoring circuit 34 generates an I-t function which is very well suited to the I-t power limit of the components in the additional path 50.

In a second time range, for example t1>700 ms, the thermally static range of the components of the additional path 50 applies instead. Therefore, only currents that do not exceed the static load capacity are permitted.

The monitoring means 34 does not have a quiescent current requirement in normal monitoring operation, i.e., when the currents into the additional path 50 are in the non-critical range. Only upwards of a configurable current threshold I1 is the monitoring means 34 (at time to) activated and requires a low supply current. Certain quiescent current requirements can thus be met.

In the event of a fault or defect of the evaluation means 21 or main controller, the monitoring circuit 34 can be used as a fallback solution and functions completely autonomously. All circuit blocks such as comparators 36, 38, 40, timing elements 44, power supply 42 can be constructed with discrete components and can thus be used cost-effectively, in particular for the motor vehicle sector.

FIG. 2 shows the individual components of the monitoring means 34, in particular of the hardware overcurrent monitoring circuit. As described, the additional path 50, which likewise connects the non-safety-relevant on-board electrical subsystem 10 to the safety-relevant on-board electrical subsystem 11, comprises the resistor 58, in particular the current-limiting resistor, and the switching means 54. A current measurement means 56 is provided, which detects the current I flowing through the additional path 50 using the resistor 58. The corresponding current measurement means 56 is a component of the monitoring circuit 34. The detected current I or a measure of the detected current I is used as an input variable for a wake-up comparator 36, for a dynamic overcurrent comparator 38 and for a static overcurrent comparator 40.

If the detected current I reaches a wake-up threshold or threshold value I1 of the wake-up comparator 36, it sends an activation signal 37 at time to or t=0 to the timing element 44, to the dynamic overcurrent comparator 38, and to a power supply 42. The static overcurrent comparator 40 is always active, but its output signal (switch-off signal) is forwarded by the timing element 44 only after t>t1. The timing element 44 is thus started at to or t=0. The circuit block of the dynamic overcurrent comparator 38 also starts its measuring amplifier. When a current I is below the wake-up threshold or threshold value I1 (I<I1), the entire monitoring circuit 34 does not require a quiescent current, since the components just mentioned are not active.

The timing element 44 operates as follows. In a first time interval of t=0 to t=t1, the dynamic overcurrent comparator 38 (depending on the measured current I) has the possibility of opening the current path or the switching means 54 of the additional path 50. For times of t>t1, the static overcurrent comparator 40 is additionally switched on with a fixed threshold value I2. The static overcurrent comparator 40 has a lower overcurrent limit 12, and therefore the static comparator 40 usually triggers earlier for t>t1. However, the dynamic comparator 38 remains active.

The dynamic overcurrent comparator 38 generates the limit value Id for pulse-like loads (for example in the order of t<700 ms). These pulse-like currents that the components of the additional path 50 can carry and also the pulse-like loads that can be supplied therewith are defined correspondingly. The dynamic overcurrent comparator 38 generates a switch-off signal 46 as a function of the current value I and the time (duration) t of the applied current I. The associated I-t function for the switch-off signal 46 can be seen in FIG. 3. The time t, in particular the switch-off time in ms, is plotted on the ordinate, the associated current pulse I in A (with the duration t) is plotted on the abscissa. The region on the left below the line does not lead to a switch-off. These load currents or current pulses I of a certain duration t are thus tolerable for the components of the additional path 50. A load profile located in the region on the right above the line according to FIG. 3 leads to the disconnection of the current flow, and therefore a switch-off signal 46 is generated, which causes the switching means 54 to open. The position and form of the switch-off of the characteristic curve according to FIG. 3 can be adapted via parameters. In principle, however, the form of the I-t function remains in the form of a decaying exponential function which approaches a value asymptotically. In general, the shorter a current flows, the higher the permitted current intensity I.

The static overcurrent comparator 40 defines a static maximum current I2 that the components of the additional path 50 can carry and also the static load that can be supplied therewith. Like the wake-up comparator 36, the static comparator 40 thus has a fixed threshold value I2 that leads to the switch-off signal 46 when reached by the measurement signal. The threshold value I2 of the static comparator 40 is greater than the threshold value I1 of the wake-up comparator 36.

Which signal of the two comparators 38, 40 ultimately leads to the switch-off of the additional path 50 depends on the routing position through the timing element 44, as symbolized by the switching means to be thrown in the timing element 44.

The power supply 42 is deactivated for a current less than the threshold value I<11 in order to avoid generating a quiescent current. For I>11, the power supply 42 is activated by the wake-up comparator 36, so that the timing element 44 and also the dynamic overcurrent comparator 38 are supplied with a defined supply voltage and a voltage threshold value.

The circuit for the current measurement means 56 is shown in more detail in FIG. 4. In order to ascertain the current I via the additional path 50, the voltage drop across the current-limiting resistor 58 is ascertained. The current-limiting resistor 58, i.e., the measuring shunt, consists of a resistor sequence 60. The resistor sequence 60 comprises numerous (for example 9 in the exemplary embodiment) resistors connected in series. Four voltage taps 62, 63, 64, 65, for example, are provided at the different resistors of the resistor sequence 60. The entire voltage drop across the resistor 58 can thus be ascertained via the two external voltage taps 62, 65. The wake-up comparator 36 and the static overcurrent comparator 40 are connected via these two external voltage taps 62, 65 in order to measure the voltage via the entire resistor sequence 60. However, the dynamic overcurrent comparator 38 has, in each case for both current directions, the measurement connection for the higher potential at the edge of the resistor sequence 60 and the measurement connection for the lower potential in the central region of the resistor sequence 60, namely the voltage taps 63, 64. The two central voltage taps 63, 64 are provided at the central measuring resistor (the fifth one in the exemplary embodiment). The functionality of the subsequent measuring and filtering circuit is thereby ensured even in the event of a short-circuit (i.e., 0 V) at one of the two on-board electrical subsystems 10, 11. The necessary residual voltage thus remains on the measurement connection at the lower potential. The monitoring means 34 is implemented bidirectionally, so that both current directions through the additional path 50 are monitored.

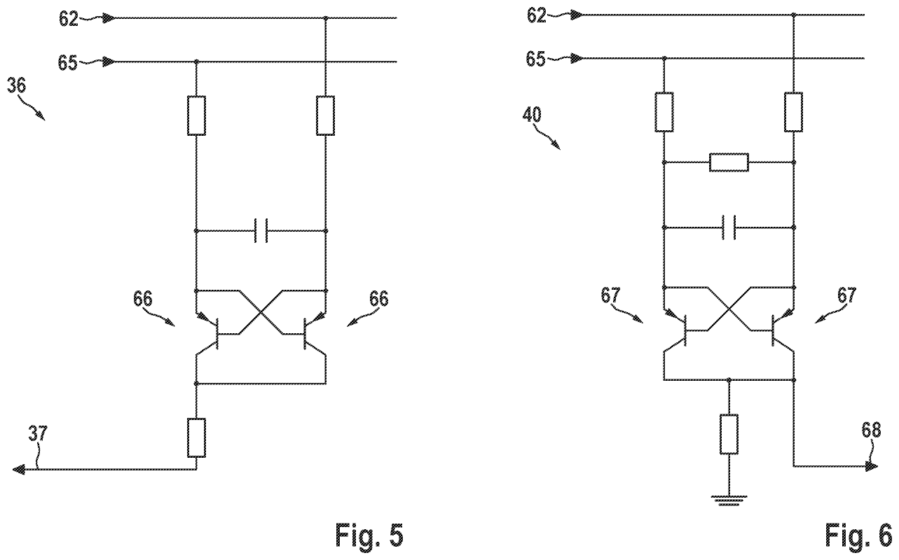

FIG. 5 shows the circuit design of the wake-up comparator 36. This circuit is realized as a bidirectional voltage comparator. Both current directions through the additional path 50 are thus apparent. The voltage drop across the current-limiting resistor 58 is applied to a base-emitter path 66 of at least one transistor in the form of the voltage taps 62, 65. If the threshold value of the base-emitter path is reached and the latter becomes conductive, the circuit generates an activation signal 37, as already described in connection with FIG. 2. In the circuit shown by way of example in FIG. 4 as a possible implementation of the wake-up comparator 36, one voltage tap 62 is electrically conductively connected via a resistor to an emitter of a first transistor and a base of a further transistor. The further voltage tap 65 is electrically conductively connected via a resistor to an emitter of the further transistor and a base of the first transistor. The collector connections of the two transistors are brought into electrically conductive contact with one another and, conducted via a resistor, the activation signal 37 is generated.

FIG. 6 shows the circuit design of the static overcurrent comparator 40. The static overcurrent comparator 40 basically resembles the bidirectional wake-up comparator 36. Since the static switch-off threshold 12 is higher than the wake-up threshold 11, the voltage drop across the current-limiting resistor 58 is divided with a voltage divider (according to the desired threshold 12) and then applied to a base-emitter path of at least one further transistor. When the threshold 12 is exceeded, the static overcurrent comparator 40 generates the switch-off signal 46 or fault signal for the additional path 50. In the circuit shown by way of example in FIG. 5 as a possible implementation of the overcurrent comparator 40, one voltage tap 62 is electrically conductively connected via a resistor to an emitter of a first transistor and a base of a further transistor. The further voltage tap 65 is electrically conductively connected via a resistor to an emitter of the further transistor and a base of the first transistor. The collector connections of the two transistors are brought into electrically conductive contact with one another and, conducted via a resistor, the fault signal 68 of the additional path 50 is generated.

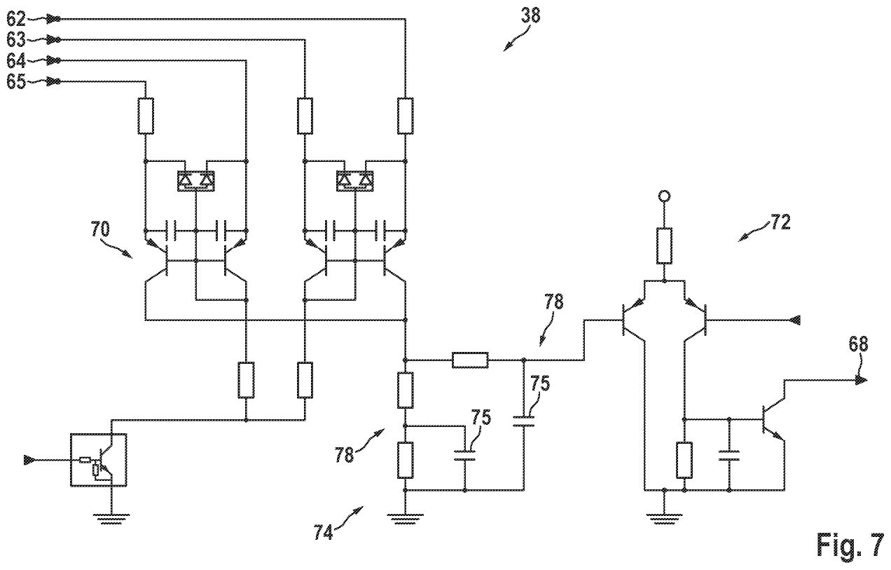

FIG. 7 shows the circuit design of the dynamic overcurrent comparator 38. It comprises multiple subfunctions, namely a differential amplifier 70, a threshold value comparator 72, and a filter 74 for the I-t characteristic shown in FIG. 3. The in particular bidirectional differential amplifier 70, which gains its input value from the voltage drop via parts of the current-limiting resistor 58, generates an output current proportional to the input value. This output current charges the capacitors 75 of the filter 74, so that a charging voltage results, which is compared with a threshold value in the comparator 72. The two first-order RC elements of the filter 74 generate the desired I-t function in cooperation with the threshold value comparator 72. The two RC elements 78 of the filter 74 are designed such that, on the one hand, very high currents via the additional path 50 are switched off very quickly and moderate currents (in the region of, for example, twice the switch-off threshold 12 of the static overcurrent comparator 40) can flow for a comparatively long time, see in particular FIG. 3. This characteristic is well suited to the maximum load capacity of MOSFETs (switching means 54) and shunt resistors (current-limiting resistor 58), which are the components to be protected in the additional path 50. The output signal of the threshold value comparator 72 forms the fault signal 68 for the additional path 50. The fault signal 68 or switch-off signal is generated when the threshold value of the dynamic overcurrent comparator 38 is reached.

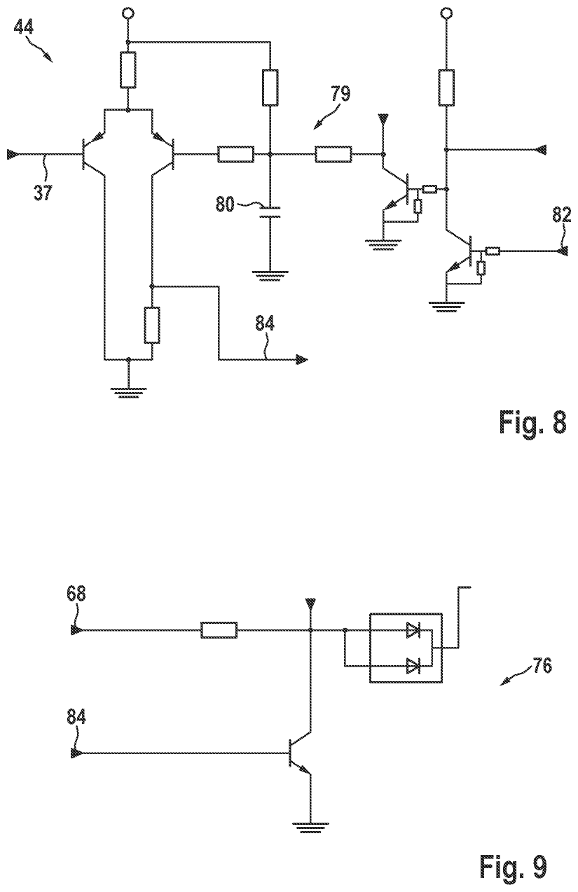

FIG. 8 shows the circuit design of the timing element 44. The timing element 44 contains a definable timer 79. If activation via the activation signal 37 takes place via the wake-up comparator 36, the charging process of a capacitor 80 begins. The power supply 92 is started via the activation signal 37. This then leads to the RC element 80 in the timing element 44 being charged. If the charging voltage of the RC element 80 reaches a threshold value, the static overcurrent comparator 40 is activated. If the charging voltage of the capacitor 80 reaches a threshold voltage, a signal change is generated at the output of the timing element or timer 79. As a result, the output signal of the static overcurrent comparator 40 is no longer suppressed (corresponding suppression signal 84) and passed through. This circuit block is particularly important for the wake-up phase from sleep mode and also in the event of a fault of the evaluation means 21 or controller (fault signal 82 of the control unit or power distributor 18) of the control unit or power distributor 18. There is therefore the possibility of interrupting this timing element 44. This occurs if the evaluation means 21 or the controller is started up fully functionally and is not in the fault state. The evaluation means 21 or the controller then assumes the protection of the entire power distributor 18, i.e., including that of the additional path 50. If the wake-up phase is not successful (or the evaluation means 21 or the controller has a fault, fault signal 82) and additionally a load (I>11, which represents a potential risk of overcurrent) flows via the additional path 50, the described overcurrent protection is active.

FIG. 9 shows the circuit arrangement for a suppression circuit 76 of the output signal of the static overcurrent comparator 40. The fault signal 68 of the additional path 50 and the suppression signal 84 as generated by the timing element 44 are supplied as input variables. If a corresponding suppression signal 84 is present, the fault signal 68 is no longer forwarded by the static overcurrent comparator 40, as indicated in FIG. 2 via the switching means in the timing element 44.

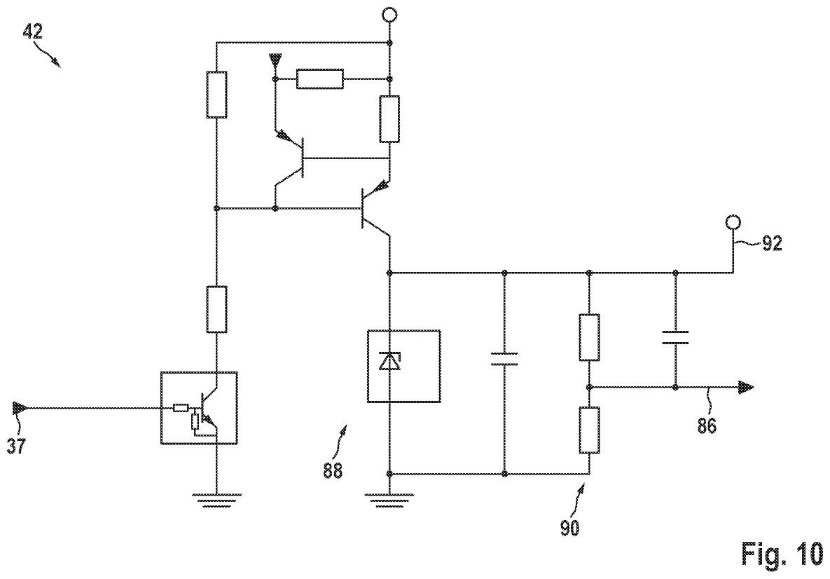

FIG. 10 shows the circuit arrangement for the power supply 42. A supply voltage 92 and a defined voltage threshold value 86 are necessary for the function of the dynamic overcurrent comparator 38 as well as for the timing element 44. However, in order to avoid causing a quiescent current, these voltages are only activated upwards of the current threshold I1 by the wake-up comparator 36 via the activation signal 37. The two voltage values are generated by means of a Zener diode 88 and a voltage divider 90. If this power supply 42 is activated, the timing element 44 and also the dynamic overcurrent comparator are thus activated by the activation signal 37.

The power distributor 18 with associated monitoring circuit 34 is arranged, for example, in a 12 V on-board electrical system 13 in a motor vehicle directly at the interface between the non-safety-relevant on-board electrical subsystem 10 and the safety-relevant on-board electrical subsystem 11, in particular an ASIL-certified on-board electrical subsystem 11. Said system comprises at least the disconnection and connection module, which consists of the main path 30 and the parallel-connected additional path 50. The monitoring means 34 is implemented bidirectionally, so that both current directions through the additional path 50 are monitored. The use, however, is not limited thereto.

1-15. (canceled)

16. A device for monitoring a power distributor of a motor vehicle, the power distributor being configured to connect and disconnect two on-board electrical subsystems, the device comprising:
at least one main path, and at least one additional path connected in parallel to the main path, the main path and the additional path being arranged between an on-board electrical subsystem for at least one safety-relevant load and a further on-board electrical subsystem for at least one non-safety-relevant load, the main path includes a switch, and the additional path includes a switch, wherein the power distributor includes at least one evaluation device configured to detect a state that is critical to the on-board electrical subsystem for the safety-critical load, including overcurrent and/or undervoltage or overvoltage at the on-board electrical subsystem for the safety-critical load, and to open the switch of the main path and/or the switch of the additional path, when the critical state is detected; and
at least one monitoring device configured to monitor, independently of the evaluation device, a current flowing via the additional path and to actuate at least the switch of the additional path.

17. The device according to claim 16, wherein the monitoring device includes at least one wake-up comparator, which activates the monitoring device when the current flowing via the additional path reaches a threshold value.

18. The device according to claim 16, wherein the monitoring device is configured to distinguish between at least two time ranges in which different threshold values for the current flowing via the additional path are provided.

19. The device according to claim 16, wherein the monitoring device includes at least one dynamic overcurrent comparator, an associated threshold value is selected as a function of a time duration during which the current flows via the additional path.

20. The device according to claim 19, wherein the monitoring device includes at least one static overcurrent comparator, which generates a switch-off signal for opening the switch of the additional path when the current flowing via the additional path reaches a further threshold value.

21. The device according to claim 19, wherein the dynamic overcurrent comparator is configured to permit a higher current for a shorter duration or a lower current for a longer duration.

22. The device according to claim 21, wherein an exponential relationship between a permitted current and an associated duration of the current is represented in the dynamic overcurrent comparator.

23. The device according to claim 16, wherein the switch of the main path is open in a sleep mode or a wake-up phase, while the switch of the additional path is closed in the sleep mode or the wake-up phase, and/or the evaluation device is not active in the sleep mode or the wake-up phase.

24. The device according to claim 20, wherein the monitoring device includes at least one timing element, which is configured such that the dynamic overcurrent comparator is active up to a time period from activation, and that after the time period including after activation is reached, the static overcurrent comparator is additionally active.

25. The device according to claim 16 wherein the monitoring device is activatable when there is a fault in the main path and/or a fault in the power distributor and/or a fault in the evaluation device.

26. The device according to claim 19, wherein the dynamic overcurrent comparator includes: (i) at least one differential amplifier, and/or (ii) at least one filter with at least one capacitor or an RC element, and/or (iii) at least one threshold value comparator.

27. The device according to claim 26, wherein the dynamic overcurrent comparator includes: (i) at least one differential amplifier, and (ii) at least one filter with at least one capacitor or an RC element, and (iii) at least one threshold value comparator, wherein at least one voltage drop across a measuring resistor or across a resistor sequence is supplied to the differential amplifier to generate an output variable proportional to the current, whereby at least the capacitor of the filter is charged, and wherein the threshold value comparator is actuated as a function of a voltage at the capacitor to generate a fault signal.

28. The device according to claim 16, wherein the monitoring device includes at least one power supply, which can be activated only when the current flowing through the additional path reaches a threshold value.

29. The device according to claim 16, wherein the additional path has at least one resistor for current limitation and/or as a measuring resistor for detecting the current.

30. The device according to claim 16, wherein the evaluation device is a hardware circuit without a controller.
